(19) United States
(12) Patent Application Publication
(10) Pub. No.: US 2009/0246709 A1
(43) Pub. Date: Oct. 1, 2009

(54) MANUFACTURING METHOD OF SEMICONDUCTOR DEVICE

(76) Inventors: Tetsuro NAKASUGI, Yokohama-shi (JP); Takashi SATO, Fujisawa-shi (JP); Kazutaka ISHIGO, Yokkaichi-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/407,142

(22) Filed: Mar. 19, 2009

(30) Foreign Application Priority Data
Mar. 25, 2008 (JP) 2008-078986

(51) Int. Cl. G03F 7/20; B28B 11/08

(52) U.S. Cl. 430/319; 264/293

(57) ABSTRACT

A manufacturing method of a semiconductor device includes preparing a first circuit pattern original plate including a first pattern part of a mark pattern, preparing a second circuit pattern original plate including a second pattern part of the mark pattern, transferring the first pattern part to a mask film on an underlying area to form a first transfer pattern part in the mask film, transferring the second pattern part to the mask film to form a second transfer pattern part in the mask film, and patterning the underlying area by using the mask film including a transfer mark pattern, which is obtained by combining the first transfer pattern part and the second transfer pattern part, as a mask to form an underlying mark pattern in the underlying area.

### CROSS-REFERENCE TO RELATED APPLICATIONS

This application is based upon and claims the benefit of priority from prior Japanese Patent Application No. 2008-078986, filed Mar. 25, 2008, the entire contents of which are incorporated herein by reference.

### BACKGROUND OF THE INVENTION

1. Field of the Invention

The present invention relates to a manufacturing method of a semiconductor device.

2. Description of the Related Art

Recently, for the purpose of achieving miniaturization of a semiconductor device, a method of performing pattern transfer twice with respect to the same layer (hereinafter referred to as “double transfer”) has been proposed (refer to Jpn. Pat. Appln. KOKAI publication No. 2007-258707). A representative example is a double exposure in which pattern exposure is performed twice with respect to the same layer.

However, according to conventional double transfer methods, mark patterns such as alignment marks and overlay inspection marks have not necessarily been optimized. Therefore, miniaturization of a semiconductor device has not been fully achieved.

### BRIEF SUMMARY OF THE INVENTION

According to a first aspect of the present invention, there is provided a manufacturing method of a semiconductor device comprising: preparing a first circuit pattern original plate including a first pattern part of a mark pattern; preparing a second circuit pattern original plate including a second pattern part of the mark pattern; transferring the first pattern part to a mask film on an underlying area to form a first transfer pattern part in the mask film; transferring the second pattern part to the mask film to form a second transfer pattern part in the mask film; and patterning the underlying area by using the mask film including a transfer mark pattern, which is obtained by combining the first transfer pattern part and the second transfer pattern part, as a mask to form an underlying mark pattern in the underlying area.

According to a second aspect of the present invention, there is provided a manufacturing method of a semiconductor device comprising: preparing a first circuit pattern original plate including a first pattern part of a first mark pattern and a second mark pattern; preparing a second circuit pattern original plate including a second pattern part of the first mark pattern and a third mark pattern; transferring the first pattern part and the second mark pattern to a mask film on an underlying area to form a first transfer pattern part and a second transfer mark pattern in the mask film; transferring the second pattern part and the third mark pattern to the mask film to form a second transfer pattern part and a third transfer mark pattern in the mask film; patterning the underlying area by using the mask film including a first transfer mark pattern obtained by combining the first transfer pattern part and the second transfer pattern part, the second transfer mark pattern, and the third transfer mark pattern as a mask, to form a first underlying mark pattern, a second underlying mark pattern, and a third underlying mark pattern in the underlying area; and selecting a desired underlying mark pattern from the first underlying mark pattern, the second underlying mark pattern, and the third underlying mark pattern.

### BRIEF DESCRIPTION OF THE SEVERAL VIEWS OF THE DRAWING

FIG. 1 is a plan view schematically showing layout positions of alignment marks formed on a semiconductor wafer, according to the first embodiment of the present invention.

FIG. 2A and FIG. 2B are plan views showing an example of alignment marks according to the first embodiment of the present invention.

FIG. 3A to FIG. 3D are sectional views for schematically showing a method of forming an alignment mark using double exposure according to the first embodiment of the present invention.

FIG. 4A to FIG. 4H are sectional views for schematically showing a method of forming an alignment mark using double patterning according to the first embodiment of the present invention.

FIG. 5A to FIG. 5D are sectional views for schematically showing a manufacturing method of a semiconductor device according to the first embodiment of the present invention.

FIG. 6 is a plan view for showing another example of alignment mark according to the first embodiment of the present invention.

FIG. 7 is a plan view for showing another example of alignment mark according to the first embodiment of the present invention.

FIG. 8 is a plan view for showing another example of alignment mark according to the first embodiment of the present invention.

FIG. 9 is a plan view for showing another example of alignment mark according to the first embodiment of the present invention.

FIG. 10 is a plan view for showing still another example of alignment mark according to the first embodiment of the present invention.

FIG. 11 is a plan view showing an example of an overlay inspection mark according to the first embodiment of the present invention.

FIG. 12 is a plan view showing another example of an overlay inspection mark according to the first embodiment of the present invention.

FIG. 13 is a plan view showing still another example of an overlay inspection mark according to the first embodiment of the present invention.

FIG. 14 is a plan view schematically showing layout positions of alignment marks formed on a semiconductor wafer, according to the second embodiment of the present invention.

FIG. 15 is a flow chart showing a method according to the second embodiment of the present invention.

### DETAILED DESCRIPTION OF THE INVENTION

Embodiments of the present invention will now be described with reference to the accompanying drawings.

### First Embodiment

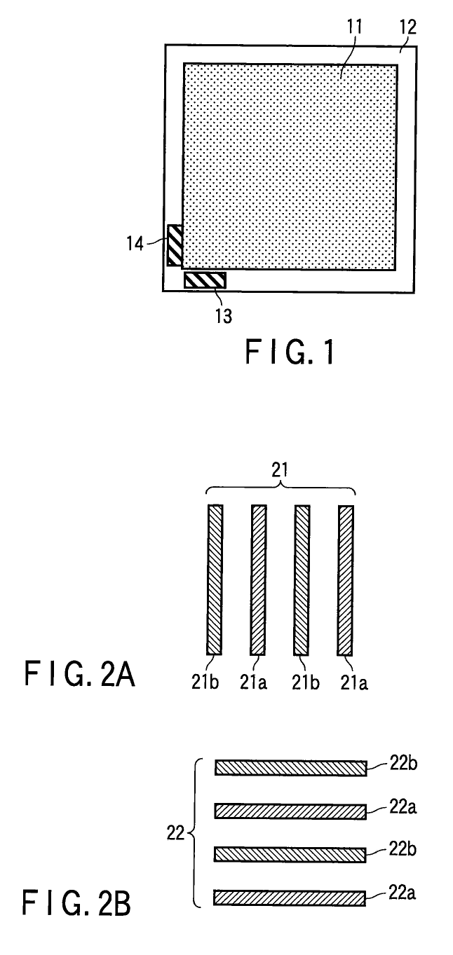

FIG. 1 is a plan view for schematically showing layout positions of alignment marks formed on a semiconductor wafer according to the present embodiment.

In FIG. 1, 11 is a circuit pattern layout area and 12 is a dicing area. 13 is an X-direction alignment mark layout part and 14 is a Y-direction alignment mark layout part. As shown in FIG. 1, the X-direction alignment mark layout part 13 and the Y-direction alignment mark layout part 14 are provided within the dicing area 12. Though the alignment mark layout parts are provided within the dicing area 12 in the example of FIG. 1, they may be provided within the circuit pattern layout area 11.

FIGS. 2A and 2B are plan views respectively showing an example of an alignment mark formed in an alignment mark layout part. FIG. 2A is a figure for showing the X-direction alignment mark 21 arranged in the X-direction alignment mark layout part 13. FIG. 2B is a figure for showing the Y-direction alignment mark 22 arranged in the Y-direction alignment mark layout part 14.

The alignment marks shown in FIGS. 2A and 2B are formed by double transfer such as double exposure and double patterning. More specifically, first pattern parts 21a and 22a of the alignment mark are formed on the basis of the first exposure using a first photomask, and second pattern parts 21b and 22b of the alignment mark are formed on the basis of the second exposure using a second photomask. A combination pattern of the pattern part 21a and the pattern part 21b is the X-direction alignment mark 21, and a combination pattern of the pattern part 22a and the pattern part 22b is the Y-direction alignment mark 22.

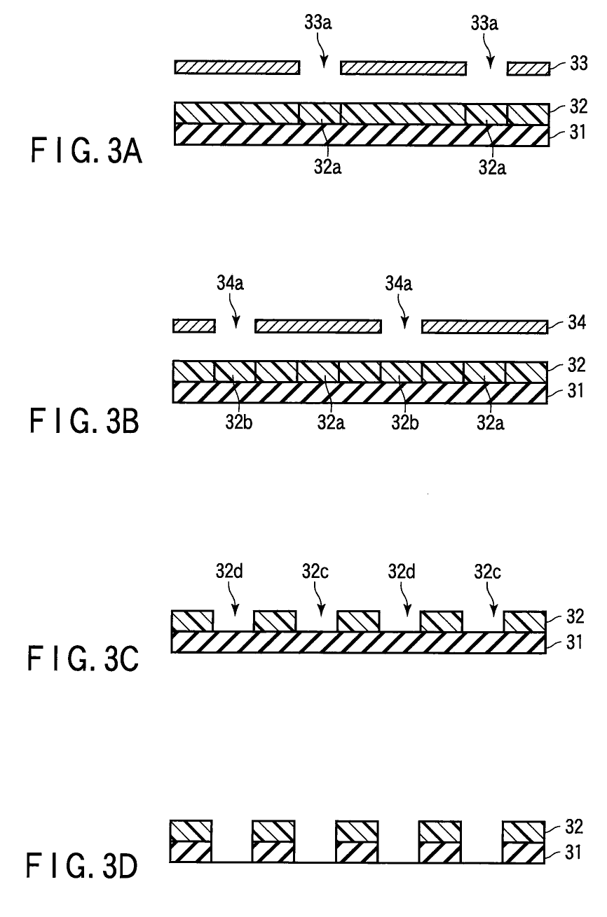

Next, a formation method of an alignment mark using the double exposure will be explained with reference to cross sectional views of process shown in FIGS. 3A to 3D. In the double exposure, pattern exposure is performed twice with respect to the same layer.

First, a photoresist film (mask film) 32 is formed on an underlying film (underlying area) 31 as shown in FIG. 3A. Examples of the underlying film 31 are an insulating film and a conducting film formed on a semiconductor substrate (not shown). Then, the first exposure is performed by using a first photomask (the first circuit pattern original plate) 33 that is preliminarily prepared, thereby transferring a pattern on the first photomask 33 to the photoresist film 32. A first part (not shown) of a circuit pattern to be transferred to the circuit pattern layout area 11 of FIG. 1 is formed on the first photomask 33. Also, on the first photomask 33, an opening pattern (light transmission part) is formed as a first pattern part 33a of the alignment mark pattern. Therefore, the opening pattern 33a is transferred to the photoresist film 32 to form an exposure part 32a.

Next, as shown in FIG. 3B, the second exposure is performed by using a second photomask (the second circuit pattern original plate) 34 that is preliminarily prepared, thereby transferring a pattern on the second photomask 34 to the photoresist film 32. A second part (not shown) of the circuit pattern to be transferred to the circuit pattern layout area 11 of FIG. 11 is formed on the second photomask 34. Also, on the second photomask 34, an opening pattern (light transmission part) is formed as a second pattern part 34a of the alignment mark pattern. Therefore, the opening pattern 34a is transferred to the photoresist film 32 to form an exposure part 32b.

Next, the photoresist film 32 is developed and exposure parts 32a and 32b are removed from the photoresist film 32 as shown in FIG. 3C. As a result, an opening pattern part (the first transfer pattern part) 32c to which the opening pattern 33a of the first photomask 33 is transferred and an opening pattern part (the second transfer pattern part) 32d to which the opening pattern 34a of the second photomask 34 is transferred are formed on the photoresist film 32.

Then, as shown in FIG. 3D, the underlying film 31 is subjected to etching (patterning) by using, as a mask, a photoresist pattern 32 including a transfer mark pattern in which the opening pattern part 32c and the opening patter part 32d are combined. As a result, an underlying mark pattern 31 corresponding to the photoresist pattern 32 is formed.

With the above processes, the alignment mark (underlying mark pattern 31) to be used for aligning layers in a subsequent process is obtained. A combination circuit pattern is formed in the circuit pattern layout area 11 of FIG. 1 on the basis of the first part of the circuit pattern formed on the first photomask 33 and the second part of the circuit pattern formed on the second photomask 34.

As explained above, according to the present embodiment, the opening pattern part (the first transfer pattern part) 32c is formed in the photoresist film 32 in a first pattern transfer process based on the first exposure, and the opening pattern part (the second transfer pattern part) 32d is formed in the photoresist film 32 in a second pattern transfer process based on the second exposure. Then the underlying film 31 is subject to patterning by using, as a mask, the photoresist pattern 32 including the transfer mark pattern which is a combination of the opening pattern part 32c and the opening pattern part 32d, thereby forming an alignment mark (the underlying mark pattern 31) as shown in FIG. 3D.

Therefore, the alignment mark (the underlying mark pattern 31) reflects both of the first exposure and the second exposure (the first pattern transfer and the second pattern transfer). Thus, utilization of the alignment mark obtained in the above manner for the alignment makes it possible to reduce alignment errors, and an optimized alignment mark is able to be obtained. That is to say, by using the obtained alignment mark of the first layer on a lower layer side for aligning the second layer on an upper layer side, alignment errors can be averaged and the alignment of the second layer with respect to the first layer can be performed appropriately. For example, though it is possible to ensure alignment accuracy of a pattern obtained through the first exposure when an alignment mark is formed on the basis of only the first exposure, it may greatly deteriorate alignment accuracy of a pattern obtained through the second exposure. According to the present embodiment, since the both of the first exposure and the second exposure (the first pattern transfer and the second pattern transfer) are reflected on the alignment mark, the above problem can be avoided.

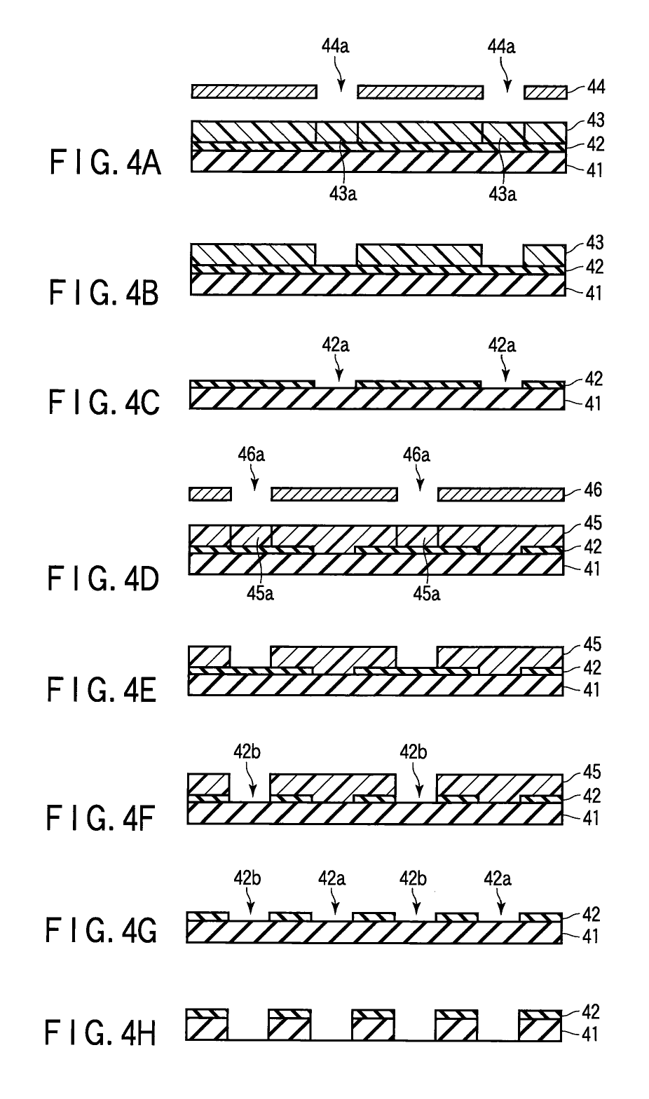

Next, a method of forming alignment mark using double patterning will be explained with reference to cross sectional views of processes shown in FIGS. 4A to 4H. In double patterning too, pattern exposure is performed twice with respect to the same layer.

First, a hard mask film 42 is formed on an underlying film (underlying area) 41 as shown in FIG. 4A. Examples of the underlying film 41 are an insulating film and a conducting film formed on a semiconductor substrate (not shown). Then, a photoresist film 43 is formed on the hard mask film 42. Subsequently, the first exposure is performed by using a preliminarily prepared first photomask (a first circuit pattern original plate) 44, for transferring a pattern on the first photomask 44 to the photoresist film 43. A first part (not shown) of a circuit pattern to be transferred to the circuit pattern layout area 11 of FIG. 1 is formed on the first photomask 44. Also, an opening pattern (light transmission part) is formed on the first photomask 44 as a first pattern part 44a of an alignment mark pattern. Therefore, this opening pattern 44a is transferred to the photoresist film 43, thereby forming an exposure part 43a in the photoresist film 43.

Next, the photoresist film 43 is developed and exposure parts 43a of the photoresist film 43 is removed as shown in FIG. 4B. As a result, a photoresist pattern 43 including an opening pattern part, which corresponds to an opening pattern 44a of the first photomask 44, is formed.

Then, the hard mask film 42 is subject to etching by using the photoresist pattern 43 as a mask as shown in FIG. 4C, and a hard mask pattern 42 including an opening part 42a corresponding to the opening part of the photoresist pattern 43 is thereby obtained. In other words, the hard mask pattern 42 including the opening pattern part (the first transfer pattern part) 42a to which the opening pattern 44a of the first photomask 44 is transferred is formed. The photoresist pattern 43 is then removed.

Then, a photoresist film 45 is formed all over the surface as shown in FIG. 4D. Subsequently, the second exposure is performed by using a preliminarily prepared second photomask (second circuit pattern original plate) 46 to transfer a pattern on the second photomask 46 to the photoresist film 45. A second part (not shown) of the circuit pattern to be transferred to the circuit pattern layout area 11 of FIG. 1 is formed on the second photomask 46. Also, an opening pattern (light transmission part) is formed, as a second pattern part 46a of the alignment mark pattern, on the second photomask 46. Therefore, the opening pattern 46a is transferred to the photoresist film 45, thereby forming an exposure part 45a in the photoresist film 45.

Next, the photoresist film 45 is developed and the exposure part 45a is removed therefrom, as shown in FIG. 4E. As a result, a photoresist pattern 45 having an opening pattern part corresponding to the opening pattern 46a of the second photomask 46 is formed.

Then, the hard mask film 42 is subject to etching by using the photoresist pattern 45 as a mask as shown in FIG. 4F. With this process, a hard mask pattern 42 including an opening part 42b corresponding to an opening part of the photoresist pattern 45 can be obtained. In other words, the hard mask pattern 42 having the opening pattern part (second transfer pattern part) 42b to which the opening pattern 46a of the second photomask 46 is transferred is formed.

Then, the photoresist pattern 45 is removed for exposing the hard mask pattern 42 as shown in FIG. 4G.

Next, as shown in FIG. 4H, the underlying film 41 is subject to etching (patterning) by using, as a mask, the hard mask pattern 42 including a transfer mark pattern which is a combination of the opening pattern part 42a and the opening pattern part 42b. The underlying mark pattern 41 corresponding to the hard mask pattern 42 is formed with this process.

With the above processes, an alignment mark (the underlying mark pattern 41) to be used for alignment between layers performed in subsequent processes can be obtained. A combination circuit pattern, which is based on the first part of the circuit pattern formed on the first photomask 44 and the second part of the circuit pattern formed on the second photomask 46, is formed in the circuit pattern layout area 11 of FIG. 1.

As explained above, similar to the example shown in FIGS. 3A to 3D, in the example shown in FIGS. 4A to 4H too, the alignment mark (the underlying mark pattern 41) reflects both of the first exposure and the second exposure (the first pattern transfer and the second pattern transfer). Therefore, according to the example shown in FIGS. 4A to 4H, it is possible to average alignment errors and thereby obtaining an optimized alignment mark, as in the example shown in FIG. 3A to 3D.

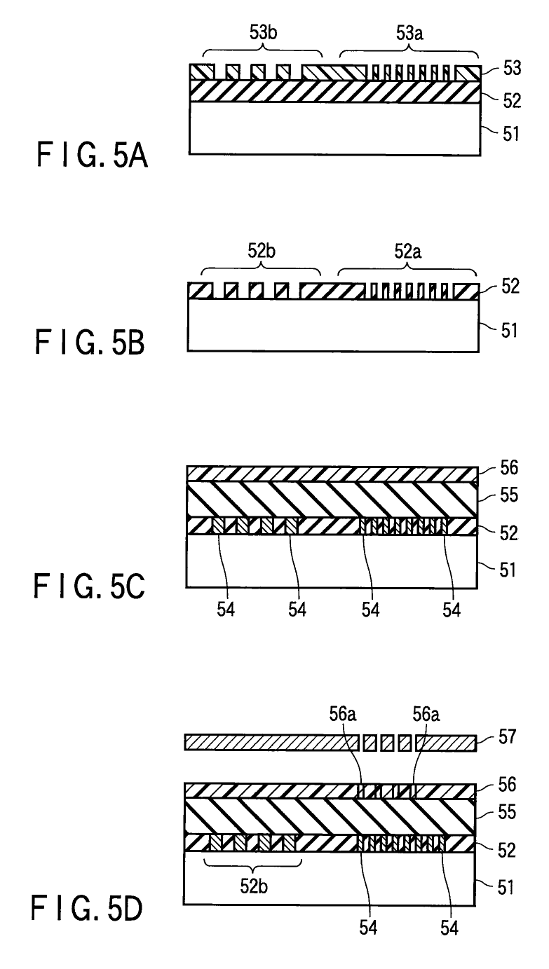

Next, a method of manufacturing a semiconductor device using the alignment mark formed with the above-described method will be explained with reference to cross sectional views of processes shown in FIGS. 5A to 5D.

First, an insulating film 52 is formed as a process target film (underlying film) formed on a semiconductor substrate 51, as shown in FIG. 5A. Then, a photoresist pattern 53 is formed on the insulating film 52. This photoresist pattern 53 is formed by using the double exposure method as shown in FIGS. 3A to 3D. The photoresist pattern 53 includes a circuit pattern 53a and an alignment mark pattern 53b. The circuit pattern 53a is arranged in a circuit pattern layout area (e.g., the circuit pattern layout area 11 shown in FIG. 1), and the alignment mark pattern 53b is arranged in an alignment mark layout part (e.g., the alignment mark layout part 13 or 14).

Then the insulating film 52 is subject to etching (patterning) by using the photoresist pattern 53 as a mask as shown in FIG. 5B. The photoresist pattern 53 is then removed. As a result, a circuit pattern 52a and an alignment mark pattern 52b are formed in the insulating film 52.

Next, an opening part of the insulating film 52 is filled with a conducting film 54 as shown in FIG. 5C, thereby forming a wiring in the circuit pattern layout area. Subsequently, an insulating film 55 is formed as a second layer on a first layer in which the insulating film 52 and the conducting film 54 are formed. Furthermore, a photoresist film 56 is formed on the insulating film 55.

Then, as shown in FIG. 5D, a pattern formed on a photomask 57 is transferred to the photoresist film 56 for forming a pattern of the second layer. An exposure part 56a is formed in the photoresist film 56 with this process. In this pattern transfer process, the photomask 57 is aligned by using the alignment mark pattern 52b formed with the double exposure. In other words, the second layer is aligned by using the alignment mark pattern 52b of the first layer formed with the double exposure.

Although subsequent processes are not shown, the photoresist film 56 is developed for forming a photoresist pattern and the insulating film 55 is subjected to patterning by using the photoresist pattern as a mask, thereby forming a pattern in the second layer.

According to the example shown in FIGS. 5A to 5D, the photoresist pattern 53 is formed as an etching mask (patterning mask) by using the double exposure method as shown in FIGS. 3A to 3D. However, a hard mask pattern may be formed by using the double patterning method as shown in FIGS. 4A to 4H. Also, although the pattern of the second layer is formed with a single exposure according to the example shown in FIGS. 5A to 5D, double exposure and double patterning may be used with respect to the second layer.

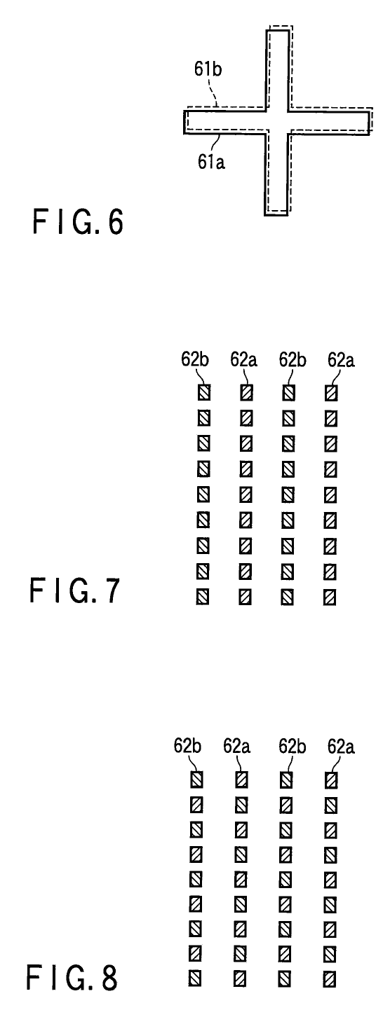

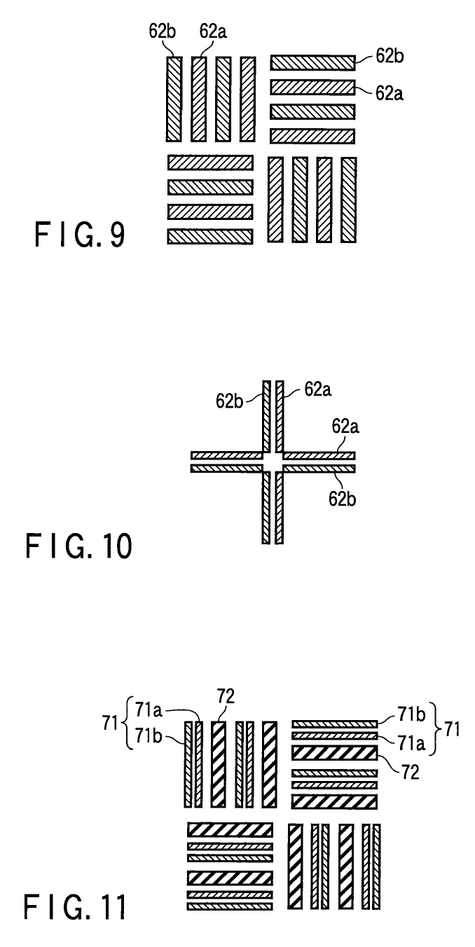

According to the example shown in FIGS. 2A and 2B of the above-described embodiment, the first pattern part and the second pattern part of the alignment mark complement each other. However, a first pattern part 61a and a second pattern part 61b of an alignment mark may be arranged at the substantially same position as shown in FIG. 6. Also, it is possible to employ various alignment marks (a first pattern part 62a and a second pattern part 62b) as shown in FIGS. 7 to 10.

Although the above embodiment explained the alignment marks, the above-described method can be also applied to formation of an overlay inspection mark. The overlay inspection mark is for inspecting overlay accuracy between layers.

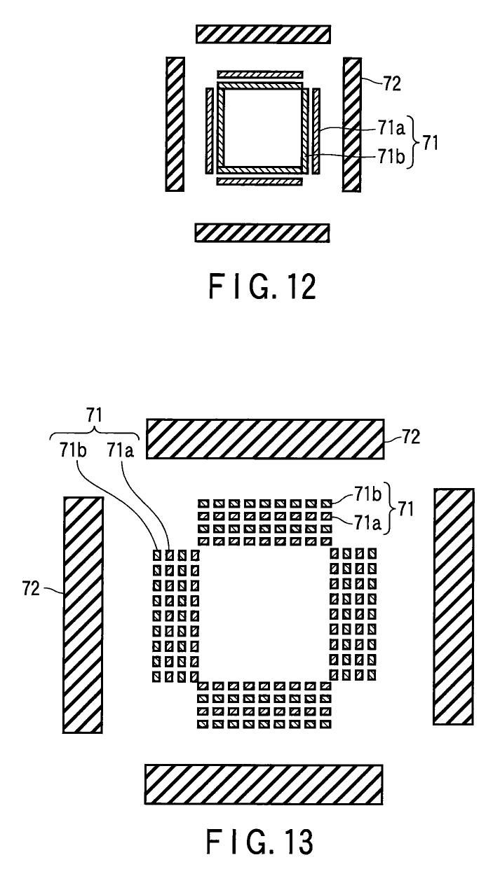

FIGS. 11 to 13 show examples of overlay inspection marks. These overlay inspection marks are formed by using double transfer such as double exposure and double patterning, in the similar manner as the above-described alignment marks are formed. That is to say, a first pattern part 71a of an overlay inspection mark is formed on the basis of the first exposure, and a second pattern part 71b of the overlay inspection mark is formed on the basis of the second exposure. The first pattern part 71a and the second pattern part 71b thereby form an overlay inspection mark 71 of the first layer on a lower side. 72 is an overlay inspection mark of the second layer on an upper side. By measuring an overlay error between the overlay inspection mark 71 of the first layer and the overlay inspection mark 72 of the second layer, overlay accuracy between the first and the second layers can be inspected.

Similar to the above-explained alignment marks, the overlay inspection mark also reflects both of the first exposure and the second exposure (the first pattern transfer and the second pattern transfer). Therefore, it is also possible to obtain an optimized overlay inspection mark, improving the overlay inspection accuracy.

### Second Embodiment

Next, the second embodiment of the present invention will be explained. Basic issues of the second embodiment are the same as the first embodiment, and explanation of the issues explained in the first embodiment are omitted.

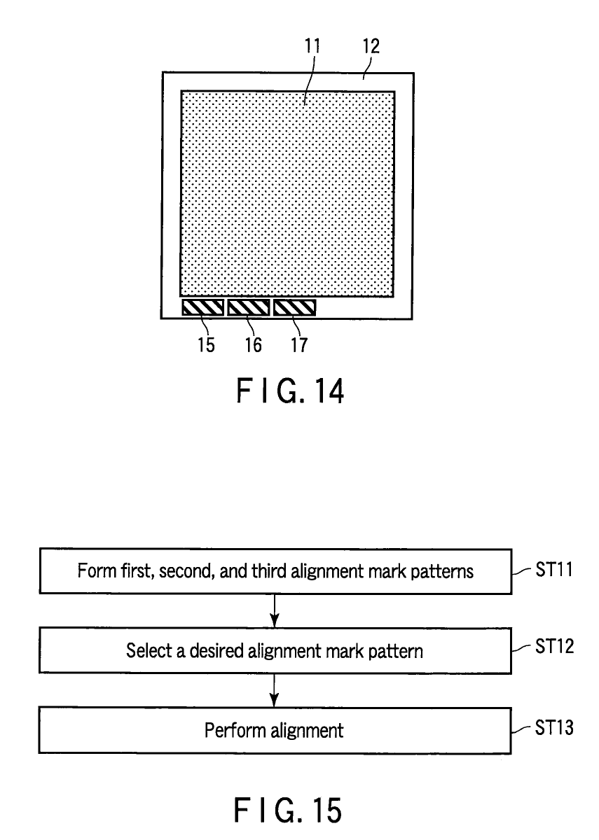

FIG. 14 is a plan view schematically showing layout positions of alignment marks formed on a semiconductor wafer according to the present embodiment.

According to the present embodiment, first, second and third alignment mark layout parts 15, 16, and 17 are provided within a dicing area 12 as shown in FIG. 14. An alignment mark pattern (a first alignment mark pattern) formed with a method explained in the first embodiment is arranged in the first alignment mark layout part 15. In other words, the first alignment mark pattern which is a combination of a first pattern part formed through the first exposure process (the first transfer process) and a second pattern part formed through the second exposure process (the second transfer process) is arranged in the alignment mark layout part 15. The second alignment mark pattern formed through the first exposure process (the first transfer process) is arranged in the second alignment mark layout part 16. Further, the third alignment mark pattern formed through the second exposure process (the second transfer process) is arranged in the third alignment mark layout part 17.

As can be known from the above-explanation, the first pattern part of the first alignment mark pattern and the second alignment mark pattern are provided on the first photomask, and these patterns are transferred in the first exposure process (the first transfer process). Also, the second pattern part of the first alignment mark pattern and the third alignment mark pattern are provided on the second photomask, and these patterns are transferred in the second exposure process (the second transfer process).

Since a basic method of forming the first, second, and third alignment mark patterns (first, second, and third underlying mark patterns) are similar to the method shown in FIGS. 3A to 3D or FIGS. 4A to 4H according to the first embodiment, explanations are omitted.

FIG. 15 is a flow chart showing an outline of a method of manufacturing a semiconductor device using the above-described first, second, and third alignment mark patterns.

Firstly, the first, second, and third alignment mark patterns are formed in the first layer with the above-described method (ST11).

Then, a desired alignment mark pattern is selected from the first, second, and third alignment mark patterns (ST12). In other words, the first, second, and third alignment mark patterns are compared for selecting the most appropriate alignment mark pattern. As for comparison methods, there are first, second, and third comparison methods to be given below. At least one of these first, second, and third comparison methods is used for selecting a desired alignment mark pattern.

The first comparison method is to compare the first, second, and third alignment mark patterns on the basis of quality of alignment mark pattern signals respectively obtained from the first, second, and third alignment mark patterns (for example, contrast or SN ratio of alignment mark pattern signals). The second comparison method is to compare the first, second, and third alignment mark patterns on the basis of alignment accuracy when preliminary alignment is performed by using the first, second, and third alignment mark patterns. The third comparison method is to compare the first, second, and third alignment mark patterns on the basis of process yield when preliminary alignment is performed by using the first, second, and third alignment mark patterns.

Next, alignment of the second layer is performed by using the alignment mark pattern selected in the process of ST12 (ST13).

As explained above, according to the present embodiment too, the first alignment mark pattern reflects both of the first exposure and the second exposure (the first pattern transfer and the second pattern transfer) as in the first embodiment. Therefore, as for the first alignment mark pattern according to the present embodiment, an advantage similar to that of the first embodiment can be obtained. Also, a desired alignment mark pattern is selected from the first, second, and third alignment mark patterns according to the present embodiment. Therefore, it is possible to perform alignment by using the second or third alignment mark pattern, when the second or third alignment mark pattern is more appropriate than the first alignment mark pattern. Thus, it becomes possible to perform more appropriate alignment.

Although the above embodiment explained about the alignment marks, the above-described method can be applied to formation of an overlay inspection mark as in the case of the first embodiment. In other words, it is possible to form first, second, and third overlay inspection mark patterns by using a method similar to the above-described method and perform overlay inspection by using a desired overlay inspection mark pattern. In the case of an overlay inspection mark too, it is possible to improve accuracy of overlay inspection by using an optimum overlay inspection mark.

The methods described in the first and the second embodiments are based on photolithography such as double exposure and double patterning. However, as for double imprint based on imprint lithography too, it is possible to apply a method similar to the methods described in the first and the second embodiments.

In imprint lithography, an imprint original plate (template) is used as first and second circuit pattern original plates, instead of a photomask. A pattern formed on the imprint original plate is pressed to a resist film formed on a semiconductor substrate, and the resist film is hardened with heat, electromagnetic wave, or pressure. The pattern formed on the imprint original plate is transferred to the resist film with this process. It is possible to form a combined mark pattern on the resist film (mask film) if the first and the second pattern parts of the mark patterns (alignment mark pattern, overlay inspection mark pattern) are respectively formed on the first and the second imprint original plates in the similar manner as the first and the second photomasks are formed in the first and the second embodiments.

In the case of using the double imprint, it is also possible to obtain a mark pattern reflecting both of the first pattern transfer and the second pattern transfer. Therefore, an advantage similar to that of the first and the second embodiments can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device comprising:
preparing a first circuit pattern original plate including a first pattern part of a mark pattern;
preparing a second circuit pattern original plate including a second pattern part of the mark pattern;
transferring the first pattern part to a mask film on an underlying area to form a first transfer pattern part in the mask film;
transferring the second pattern part to the mask film to form a second transfer pattern part in the mask film; and
patterning the underlying area by using the mask film including a transfer mark pattern, which is obtained by combining the first transfer pattern part and the second transfer pattern part, as a mask to form an underlying mark pattern in the underlying area.

2. The method according to claim 1, wherein the underlying mark pattern is used as an alignment mark.

3. The method according to claim 2, further comprising performing alignment by using the underlying mark pattern.

4. The method according to claim 1, wherein the underlying mark pattern is used as an overlay inspection mark.

5. The method according to claim 4, further comprising performing an overlay inspection by using the underlying mark pattern.

6. The method according to claim 1, wherein the first transfer pattern part and the second transfer pattern part are formed on the basis of a double exposure method, a double patterning method, or a double imprint method.

7. The method according to claim 1, wherein the first and the second circuit pattern original plates are photomasks for photolithography.

8. The method according to claim 1, wherein the first and the second circuit pattern original plates are templates for imprint lithography.

9. The method according to claim 1, wherein the first transfer pattern part and the second transfer pattern part are in a relation of complementing each other.

10. A manufacturing method of a semiconductor device comprising:
preparing a first circuit pattern original plate including a first pattern part of a first mark pattern and a second mark pattern;
preparing a second circuit pattern original plate including a second pattern part of the first mark pattern and a third mark pattern;
transferring the first pattern part and the second mark pattern to a mask film on an underlying area to form a first transfer pattern part and a second transfer mark pattern in the mask film;
transferring the second pattern part and the third mark pattern to the mask film to form a second transfer pattern part and a third transfer mark pattern in the mask film;
patterning the underlying area by using the mask film including a first transfer mark pattern obtained by combining the first transfer pattern part and the second transfer pattern part, the second transfer mark pattern, and the third transfer mark pattern as a mask, to form a first underlying mark pattern, a second underlying mark pattern, and a third underlying mark pattern in the underlying area; and
selecting a desired underlying mark pattern from the first underlying mark pattern, the second underlying mark pattern, and the third underlying mark pattern.

11. The method according to claim 10, wherein the selected underlying mark pattern is used as an alignment mark.

12. The method according to claim 11, further comprising performing alignment by using the selected underlying mark pattern.

13. The method according to claim 10, wherein the selected underlying mark pattern is used as an overlay inspection mark.

14. The method according to claim 13, further comprising performing an overlay inspection by using the selected underlying mark pattern.

15. The method according to claim 10, wherein the first transfer pattern part and the second transfer pattern part are formed on the basis of a double exposure method, a double patterning method, or a double imprint method.

16. The method according to claim 10, wherein the first and the second circuit pattern original plates are photomasks for photolithography.

17. The method according to claim 10, wherein the first and the second circuit pattern original plates are templates for imprint lithography.

18. The method according to claim 10, wherein the first transfer pattern part and the second transfer pattern part are in a relation of complementing each other.
